(19) United States
(12) Patent Application Publication
(10) Pub. No.: US 2005/0219076 A1
(43) Pub. Date: Oct. 6, 2005

(54) Information management system

(76) Inventor: Michael Harris, Evanston, IL (US)

Correspondence Address: SWIDLER BERLIN LLP, 3000 K STREET, NW, BOX IP, WASHINGTON, DC, 20007, US

(21) Appl. No.: 10/805,273

(22) Filed: Mar. 22, 2004

(51) Int. Cl. H03M 7/34

(52) U.S. Cl. 341/51

(57) ABSTRACT

A method for analyzing a given set of data and then compressing the data based on the analysis is disclosed. The method includes a system for compressing and managing data using, for example, a computer based user interface. Also included are a plurality of compression algorithms that may be used to determine the optimal compression ratio for a given set of data. The algorithm that produces the optimal compression ratio may then be used to iteratively compress the given set of data. Preferably, each set of data may be managed, compressed, and decompressed based on the computer based user interface. This may allow a user to optimally compress, and then decompress, selected sets of data as desired. The user interface, preferably a graphical user interface, may be capable of managing the compressed and uncompressed data. Preferably, the user interface allows data to be visually displayed and manipulated. The manipulation may include, for example, manually or automatically archiving, editing, compressing, and decompressing.

### FIELD OF THE INVENTION

The present invention relates to a method for compressing and managing data based on a computer based visual interface. More specifically, the present invention relates to a method of compressing and managing data using a plurality of compression algorithms to determine an optimal compression ratio.

### BACKGROUND OF THE INVENTION

Memory storage devices, such as Read-Only Memory (ROM) have been used in many different types of electronic devices. These devices range from video games, to computers, to hand held Personal Digital Assistants (PDA's). Despite the wide variety of applications in which memory storage devices are employed, each application shares one similar goal. That is, the desire to maximize the amount of data that can be stored in a memory. Two prominent reasons for this common approach are that memory is expensive, and consumes a large amount of space. Over the years, integrated circuit technology has advanced, allowing a greater amount of data to be stored in increasingly smaller amounts of space. However, with advances in memory storage capability have come advances in other areas of technology. Electronic devices now store computer programs that consume large amounts of memory. Additionally, modem technologies such as handheld music players require large amounts of memory to store songs and other data. Thus, despite the advances in circuit technology, the desire to store large amounts of data in a small amount of space has continued to increase.

In addition to advancing integrated circuit technology, many manufacturers sought to maximize the amount of data that can be stored in a memory by compressing data for storage. With the invention of networks, such as the Internet, data compression techniques acquired a new importance. In order to transmit information between two or more points, large files often take long amounts of time to be completely transmitted. Thus, compressing files allows transmission times to be reduced. Many different data compression techniques have been used to maximize the amount of available storage space in a memory. Some methods involve hardware, such as analog to digital converters, filters, and coders and decoders. Other more sophisticated technologies use mathematical algorithms in order to compress data.

Typically data compression tools are limited to a single algorithm that removes bit level redundancies before data is stored or transmitted. Alternately, some of these methods use a single algorithm to perform more than one compression using the same algorithm.

Other compression technologies have employed mathematical algorithms to perform compression on a “block,” or predetermined portion of data. These methods have the advantage of compressing data quickly. However, they often sacrifice optimal compression for speed. Other methods have been specifically tailored for a particular type of data, such as audio, video, or text. Some compression methods have employed more than one algorithm to compress a set of data. However, these methods typically involve rigidly using the one or more algorithms in a set sequence to compress data. Each of these methods, however, lacks the ability to analyze the data before determining which algorithms provide optimal compression.

In addition to the disadvantages of existing compression methods described above, typical compression methods do not provide an information management tool for managing compressed files. For example, typical compression methods do not provide a way to select and decompress a single file that is compressed within a group of files. In addition, typical compression methods do not provide a method for automatically or manually managing and archiving files according to predetermined criteria. Thus, there is a large area for improvement over existing compression techniques.

The Total Cost of Ownership in managing data consists of two major functional areas 1) the hardware required to support data storage and archiving requirements, and 2) the management of this data. A continuing need exists for data compression methods capable of analyzing and compressing data, while providing efficient and effective information tools to optimize performance.

### SUMMARY OF THE INVENTION

The present invention substantially reduces the disadvantages of prior art compression methods by providing a method for analyzing a given set of data and then compressing the data based on the analysis. The present invention includes a system for compressing and managing data using, for example, a computer based user interface. Also included are a plurality of compression algorithms that may be used to determine the optimal compression ratio for a given set of data. The algorithm that produces the optimal compression ratio may then be used to iteratively compress the given set of data. Preferably, each set of data may be managed, compressed, and decompressed based on the computer based user interface. This may allow a user to optimally compress, and then decompress, selected sets of data as desired.

In one embodiment, the present invention comprises a data compression method. The method preferably includes analyzing data based on a plurality of algorithms to determine a compression ratio for each algorithm. The data may then be compressed based on the algorithm that produces the best compression ratio. It may be desirable for the compressed data to include at least one index file that references the algorithm that produces the best compression ratio. In one embodiment, the compressed data may be decompressed based on a last index file that is attached to the data.

In one embodiment, the algorithms preferably compress data by removing and indexing repeating bit patterns. As a by-product, the data has repeating bit patterns removed and indexed no longer has a predictable format. Thus, the compression method according to the present invention is capable of generating an encrypted data stream output. In one embodiment, the data compression may be initiated based on a command from a user interface. It may occasionally be desirable to decompress a portion of the compressed data without decompressing the remaining portion of the data. This may be achieved based on a command issued by the user interface. In other embodiments, it may be desirable to introduce additional data. In such embodiments, the additional data may be compressed and associated with the compressed data automatically. To allow a user to easily identify compressed data using the user interface, a descriptive tag may be compressed and associated with the compressed data.

In another embodiment, the present invention comprises a method for compressing data for transmission. The method includes analyzing data based on a plurality of algorithms to determine a compression ratio for each algorithm. The data is then compressed a first time based on the algorithm that produces the best compression ratio. Preferably, the compressed data may be analyzed based on the plurality of algorithms to determine a compression ratio for each algorithm. Then, the data may be compressed iteratively based on the algorithm that produces the best compression ratio.

In this embodiment, the algorithms preferably remove repeating bit patterns in order to perform the compression. It may be desirable for a first index file to be attached to the data at substantially the same time as the data is compressed a first time. The index file is be updated for each successive iteration. It is desirable for the index file to reference the algorithm that produces data with the least number of bits. When it is desirable to decompress the compressed data, the decompression may be performed based on the last index file that is attached to the data. In other embodiments, a portion of the compressed data may be decompressed based on a command from a user interface. In some applications, it may be desirable to select additional data to be compressed and associated with the already compressed data. Preferably, this is performed automatically. In order to aid a user in determining the contents of compressed data, a descriptive tag may be compressed and associated with the compressed data based on a command from the user interface.

In another embodiment, the present invention comprises a method for transferring a digital identification mark with compressed data over a data transmission medium. The method includes compressing data based on a plurality of algorithms to determine a data compression ratio associated with each algorithm. Then, the data is iteratively compressed based upon using the algorithm that produces the best data compression ratio. Preferably, a compressed digital identification mark having a unique authentication code may then be generated. The digital identification mark may then be compressed with the second set of compressed data to produce a single mass of compressed data. Preferably, the single mass of compressed data may be transmitted over a data transmission medium.

### BRIEF DESCRIPTION OF THE DRAWINGS

Further features and advantages of the invention can be ascertained from the following detailed description that is provided in connection with the drawing(s) described below:

FIG. 1 is a block diagram showing an overview of one embodiment of the present invention;

FIG. 2 is a diagram showing one embodiment of a graphical user interface;

FIG. 3 is a block diagram showing an overview of exemplary steps in the decompression process;

FIG. 4 is a block diagram showing an overview of exemplary steps in the editing process; and

FIG. 5 is a block diagram showing an overview of one embodiment of the transfer of software between a server and a user's computer.

### DETAILED DESCRIPTION OF THE PREFERRED EMBODIMENTS

Data compression methods have a wide variety of applications. Traditionally, these methods were employed to maximize the use of storage space in a memory. Data compression was necessary because of the high cost of memory, such as Read-Only Memory (ROM). Many data compression methods employ mathematical algorithms that allow compressed data to occupy a smaller amount of space than the original, uncompressed data. With the invention of the Internet, data compression has found new importance. Data compression techniques are now used to compress data before it is transmitted from one point to another. Compressing data before it is transmitted has many advantages, including allowing data to be transmitted between two or more points as quickly as possible.

The data compression methods that are currently available have several limitations. One limitation is that many methods employ only one algorithm to compress a given set of data. Other methods use more than one algorithm, although these methods often compress data by using the algorithms in a set sequence. In addition to the number and sequence of algorithms that are used, many compression techniques perform compression on a “block” of data, or at the bit level. Each of these methods, however, has the disadvantage of being unable to adapt to a given set of data. One disadvantage of not being able to adapt to a given set of data is that data may not always be compressed in the most efficient manner.

The present invention substantially reduces the disadvantages of prior art compression methods by providing a method for analyzing a given set of data and then compressing the data based on the analysis. The present invention includes a system for compressing and managing data using, for example, a computer based user interface. Also included are a plurality of compression algorithms that may be used to determine the optimal compression ratio for a given set of data. The algorithm that produces the optimal compression ratio may then be used to iteratively compress the given set of data. Preferably, each set of data may be managed, compressed, and decompressed based on the computer based user interface. This may allow a user to optimally compress, and then decompress, selected sets of data as desired.

Compression and Decompression

As mentioned above, the present invention may be capable of using a plurality of algorithms to compress a given set of data. In one embodiment, it may be desirable for the algorithms to compress the given set of data at the bit level. One advantage of using an algorithm that compresses data at the bit level is that optimal compression may be achieved. Another advantage of bit level compression is that the algorithms may compress any type of data, for example, audio, video, text, and the like. Thus, the present invention may be capable of performing compression without regard to the type of data being used, which allows greater flexibility. In a preferred embodiment, the present invention is not intended to be limited to any type of algorithm. For example, in one embodiment, the plurality of algorithms may perform bit level compression using any desired method. The algorithms may perform compression based on, for example, removing repeating bit patterns. In this embodiment, a given algorithm preferably removes and indexes repeating bit patterns in order to remove any redundancy. Preferably, algorithms that remove and index repeating bit patterns are lossless. In other words, substantially no information is lost during the removal and indexing of the repeating bit patterns. In another embodiment, a well known compression algorithm may be used. Additionally, a combination of algorithms that perform compression based on different methods may be used.

In one embodiment, the present invention may be used with any number of algorithms. Preferably, the number of algorithms may be about 500 or less. More preferably, the number of algorithms that may be used is about 50 or less, and most preferably the number of algorithms that may be used is about 20 or less.

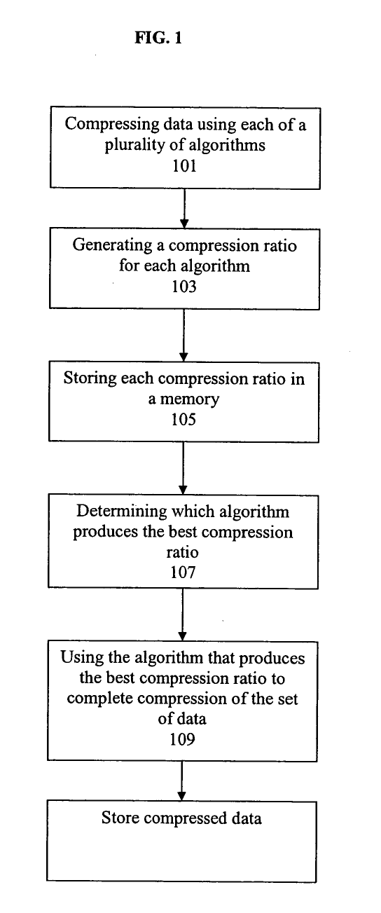

FIG. 1 is a block diagram showing an overview of one embodiment of the present invention. In one embodiment, the present invention may be capable of analyzing a given set of data, which may have any desired size. Preferably, a processor may be used to analyze the set of data based on the plurality of algorithms. In this embodiment, the analysis comprises compressing the set of data using each of the plurality of algorithms 101. After compressing the data using each of the plurality of algorithms, a compression ratio may be generated for each algorithm 103. The compression ratio may preferably be stored in a memory that is operatively connected to the processor, as shown in step 105. In one embodiment, the compression ratio may be the ratio of the size of the compressed file to the original size of the file. In other embodiments, the compression ratio may be the ratio of the size of the uncompressed file to the size of the compressed file. Regardless of the method used to calculate the ratio, it is desirable that the ratio is calculated in a substantially similar manner for each algorithm. This provides the advantage of allowing the processor to compare the various compression ratios's in order to determine which algorithm provides the most optimal compression relative to the other algorithms. Another advantage of compression based on determining a compression ratio is that any type of algorithm may be used, as described above. It may be desirable to use algorithms that perform compression based on different methods in order to determine the best compression ratio for a given set of data.

In one embodiment, uncompressed data may be compressed up to an optimal amount in order to determine a compression ratio for each of the plurality of algorithms. Preferably, the data may be compressed by between about 10% and 90% of its original size. More preferably, the data may be compressed by between about 25% and 90%s, and most preferably the data may be compressed by between about 35% and 90% of its original size. One advantage of compressing the data up to a desired percentage of its original size is that an accurate compression ratio may be generated without using the processor resources that are needed to completely compress the data. This may result in both time and cost savings.

After each of the plurality of algorithms have been used to determine a compression ratio, the processor compares the compression ratio's to determine which algorithm produces the best compression ratio, shown in step 107. In one embodiment, the algorithm that produces the best compression ratio may be used to complete the compression of the set of data, as shown in step 109. Though the compression has been described for a single set of data, it will be understood that the compression may be repeated for a plurality of sets of data.

In some embodiments, it may be desirable to perform compression iteratively. In other words, it may be desirable to perform compression on the data that has already been compressed. Data that is compressed a first time may be capable of further compression. Iterative compression allows the data to be compressed a plurality of times until the data may no longer be compressed, or alternately, until it is no longer desirable to compress the data. In some embodiments, it may be desirable to limit the number of times data is compressed to preserve processing power, to save time, to reduce cost, and the like.

In an embodiment where iterative compression may be desirable, the compression may be performed by the processor for each of the plurality of algorithms in order to determine a compression ratio, as described above. After each of the plurality of algorithms have been used to determine a compression ratio, the processor compares the compression ratio's to determine which algorithm produces the best compression ratio. In one embodiment, the algorithm that produces the best compression ratio may be used to complete the compression of the set of data. In one embodiment, after the set of data is compressed a first time, steps 101-109 may be repeated. Preferably, the processor compresses the compressed data to between about 50% to 90% of its original size.

In one embodiment, the compression may be performed using each of the plurality of algorithms in order to determine a second compression ratio. Once the compression ratios are determined, they may be compared by the processor to determine which algorithm produces the best compression ratio for the data that is compressed a first time. Preferably, the algorithm that produces the best compression ratio may be used to compress the data a second time. In this embodiment, the algorithm selected for the second compression may be the same, or different than the algorithm selected for the first compression.

In another embodiment, iterative compression may be performed using the same algorithm for each iteration. In such an embodiment, the uncompressed data may be compressed up to a predetermined amount. The compression may be performed by the processor for each of the plurality of algorithms in order to determine a compression ratio, as described above. After each of the plurality of algorithms have been used to determine a compression ratio, the processor compares the compression ratio's to determine which algorithm produces the best compression ratio. In one embodiment, the algorithm that produces the best compression ratio may be used to complete the compression of the set of data. In this embodiment, the same algorithm may be used to compress the data a second time. The compression using the same algorithm may be performed a plurality of times until further compression is undesirable or impossible. Alternately, the same algorithm may be used for the second compression, and a different algorithm may be used for successive compressions. In this embodiment, after the same algorithm is used to perform two compressions, a compression ratio is determined for each of the plurality of algorithms, as described above. The compression ratios are then compared to determine which algorithm produces the best compression ratio. The algorithm that produces the best compression ratio may then be used to perform the third compression. In some embodiments, this process may be repeated a plurality of times until further compression is not possible or undesirable.

In embodiments where iterative compression is performed, it may be desirable to limit the scale of compression by either the number of data compression algorithms used or times the data is compressed. As described above, this may be desirable to limit the time required for compression, reduce cost, and the like. In one embodiment, the processor may determine how many times a set of data should be compressed based on the compression ratios for each algorithm. This processor may make this determination in any desirable manner. In one embodiment, the compression may be repeated until substantially no additional repeating binary patterns may be removed. In another embodiment the processor may determine how many iterations of compression to perform based on the change in the compression ratios. For instance, in one embodiment described above, each of the plurality of algorithms is used to determine a compression ratio for the data that has been compressed a first time. In this embodiment, the processor may compare the best compression ratio to the best compression ratio that was determined for the uncompressed data. In one embodiment, if the percentage change in the compression ratios is substantially small, the processor may determine that no further compression is desirable. Preferably, compression may no longer be performed when the percentage change in the compression ratio is less than 5%. More preferably, compression may no longer be performed when the percentage change in the compression ratio is less than 2%, and most preferably compression may no longer be performed when the percentage change in the compression ratio is less than 0.5%. In another embodiment, compression may be performed a predetermined number of times. In such an embodiment it may be preferable to perform compression about 6 times or less. More preferably, compression may be performed about 3 times or less.

At substantially the same time as each set of data is compressed, it may be desirable to create one or more files that include information on how to reconstruct the original data to its decompressed format. In one embodiment, an index file may be created for the set of data at substantially the same time as each set of data is compressed. It may be desirable for the index file to include information on how to decompress the file including, but not limited to, the algorithm that was used to compress the data. In embodiments where iterative compression may be performed, a substantially separate index file may be created for each compression. It may be desirable for each index file to indicate which compression it is associated with, such that a processor may be capable of reconstructing the original decompressed file based on each of the plurality of index files. In one embodiment, this may be accomplished by attaching the index files to the compressed files in a particular order. In other embodiments, this may be accomplished by including identifying information in the plurality of index files that indicates the order in which the processor should reference the files to reconstruct the original, uncompressed data. It may be desirable to store the one or more index files and the compressed data to a memory such that it is accessible to the processor.

As mentioned above, the present invention may be capable of compressing more than one set of data. The sets of data may be compressed at substantially different times or they may occur substantially simultaneously. In one embodiment, it may be desirable to compress a second set of data after a first set of data has been completely compressed. In such an embodiment, each set of data may be compressed based on the algorithm that produces the best compression ratio, as described in detail above. After the compression of the second set of data is completed, the second set of compressed data may be stored in the memory with the first set of compressed data. In some embodiments, it may be desirable to compress several sets of data together. For instance, it may be preferable to store a plurality of sets of associated data together. In such an embodiment, the user interface, as described below, may be capable of providing an indicator that shows the boundaries between each of the plurality of sets of data. The indicator may include, but is not limited to, a flag, header, footer, and the like. In this embodiment, the indicator may allow the user interface to decompress one of the plurality of sets of data without decompressing the other sets of data. One advantage of this method of decompression may be that a desired set of data may be decompressed while minimizing the time and expense necessary for the data to be decompressed. Additionally, storage space in a memory is typically limited. Decompressing each of the plurality of sets of data when it is only desirable to access a single set of data may be unfeasible due to space limitations. In other words, the available memory storage space may be sufficient to decompress one of the plurality of sets of data, but insufficient to decompress each of the plurality of sets of compressed data.

In many applications, encryption may be important to protect confidential information. This may be especially true for applications that involve transmitting sensitive information over a wide area network (WAN), such as the Internet. In addition, it may be desirable to encrypt information that may be stored to a memory, such as a disk or the like, to prevent it from being decoded by an unauthorized user. As described above, in one embodiment one or more of the plurality of algorithms may compress data by removing and indexing repeating bit patterns. In this embodiment, the data may be encrypted as a by product of the compression. In other words, by removing and indexing repeating bit patterns, the compressed data is unintelligible until it is decompressed and/or reconstructed. One advantage of the encryption may be that the data may not be decompressed without knowledge of the algorithms and the order in which they should be used to decompress the file. Another advantage of compressed data is the encryption that results because the data does not have a predictable file format. This may be desirable because viruses and other harmful or malicious codes or data strings typically attach themselves to data that is formatted in a particular manner. Removing and indexing repeating bit patterns substantially minimizes the ability of malicious viruses or codes being able to attach to the compressed data. In other embodiments, the compressed data may be encrypted using other methods, such as separate software programs.

As described above, data may be compressed using one or more algorithms. In these embodiments, an index file including the algorithm used for compression may be linked to the compressed data. When it is desirable to access the original data, the index files may be referenced in order to reconstruct the data to its original format. In one embodiment, compressed data may be decompressed and reconstructed one file at a time or collectively using data in the index as new files are added, resulting in the compression being optimized to include the new data, which is reflected in the index.

The Interface

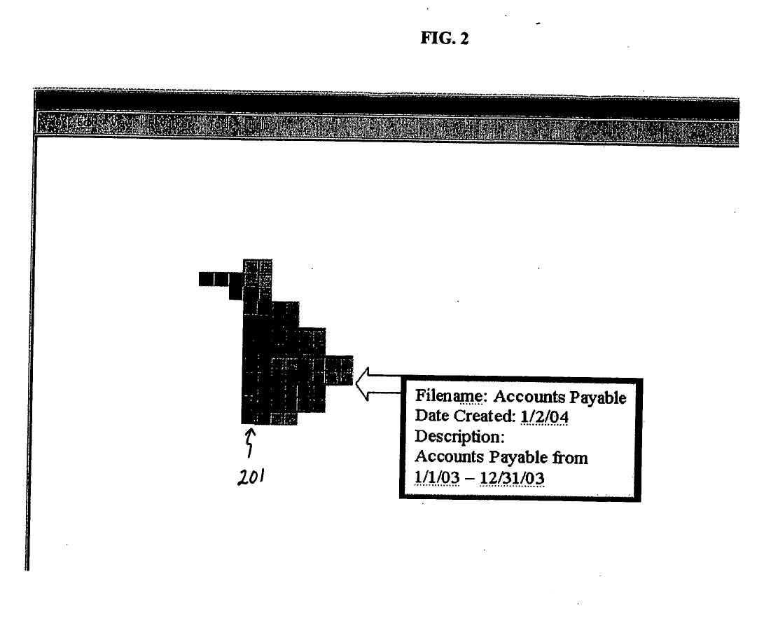

In one embodiment, the present invention may be capable of performing data compression based on a user interface. The user interface may include, but is not limited to, a graphical user interface. FIG. 2 is a diagram showing an exemplary graphical user interface. Preferably, the graphical user interface may be displayed using a computer or computing device. The user interface may allow a user to compress data on a single computer. Alternately, the user interface may allow an administrator, such as a network administrator, to reduce the space consumed by data storage within a server, database, or other networked computing device.

In one embodiment, the user interface may be used to perform a variety of functions. This may include, for example, initiate data compression, managing files, and the like. As is well known to those skilled in the art, files include data and are typically accessible using a computer, computing device, processor, and the like. Each file may comprise one or more sets of data. In this embodiment, a user may select the one or more files to compress by choosing the files from, for example, a directory. The desired files may be selected and “dragged,” or otherwise moved, to a set of compression file folders. The compression file folders allow the files to be separated according to, for example, their importance. The files may be separated according to user-defined specifications. Accordingly, the file folders may be customizable to separate files according to any desired criteria. In one embodiment, there are three compression file folders corresponding to, high, medium, and low importance levels. The desired files may be selected and moved to one of the compression file folders based on the importance level assigned to them by a user. However, in other embodiments, the file folders may have different labels and divide the files into categories based on other desired criteria. In another embodiment, one or more directories comprising a plurality of files may be moved into one of the compression file folders. In this embodiment, each of the files may be compressed and stored in the memory. A compression ratio is determined for each file in the directory, which allows each file to be compressed separately. This also provides the advantage of allowing each file in the directory to be decompressed individually, as described in more detail below.

In one embodiment, after moving the desired files to the compression file folders, the files are compressed as described above. Each file may correspond to one or more sets of data, as described above. Accordingly, each file may be compressed based on one or more algorithms that produce the best compression ratio for each file. This process may be repeated for each of the files that are placed into the compression file folders. In this embodiment, the compression of the files is transparent to the user. In other words, it may only be necessary for the user to move the file or files to one of the compression file folders in order to compress the files. From a user's perspective, the files appear to be automatically compressed and stored subsequent to being moved into the compression file folders.

In this embodiment, at substantially the same time that each file is compressed, an associated index file may be created. The index file preferably comprises information that may be used to reconstruct the original file. The index file may include, but is not limited to, the one or more algorithms used to compress the original file. It may be preferable to link the index file and the compressed file. This may be accomplished using any desired method, such as adding the index file to a desired portion, for example, the beginning or end, of the compressed file. Linking the one or more index files to the compressed file may facilitate decompression and reconstruction of the file. After linking the index file and the compressed file, the files are preferably saved to a memory, such as a computer's ROM or the like.

In one embodiment, a user may create a descriptive tag for each compressed file. This may be desirable in embodiments where a large number of files may be compressed. The descriptive tag may be, for example, a metatag. The metatag may include any text desired by the user, such as a description of the compressed files contents. In other embodiments, the descriptive tag may include audio, video, or the like. It may be desirable for the metatag to be compressed according to the method described above. Preferably, the metatag may be linked to the compressed file and the index file. The metatag may be linked to the file in any desirable manner, for example, by attaching it to the beginning or end of the compressed file or index file. Additionally, a password may be associated with each compressed file to control file access. This may be particularly preferable in applications involving the transmission of files from one user to another.

As mentioned above, the user interface may include a graphical user interface, or graphical display, shown in FIG. 2. In one embodiment, the graphical interface displays a representation of the files based on the importance level assigned to them by the user. The graphical user interface preferably represents the compressed files by associating colored squares 201 with the compressed files. It may be desirable to match the color of the squares with their associated level of importance, as assigned by the compression file folders. In one embodiment, red squares are associated with files of high importance, yellow square are associated with files of medium importance, and green squares are associated with files of low importance. One advantage of the color coded graphical representation of the files is that a desired file may be more easily located based on its assigned importance. Another advantage of the color coded graphical representation is that the files may be archived after a desired date based on their importance.

The user interface may also be used to search the compressed files by, for example, a category, keyword, and the like. In one embodiment, keywords of interest may be entered into a search page accessible using the user interface. A computer processor may then be used to perform the search, whose results may be displayed based on the user interface. In such an embodiment, the results of the search may be displayed using the graphical display. The files that include the searched keywords may be displayed according to their importance using the representations of red, yellow, and green squares described above. A pointing device, such as a computer mouse, may be used to scroll over a desired square. As the mouse cursor is placed over a red, yellow, or green square, the compressed filename and metatag information may be displayed. Allowing a user to view the name of the file and the metatag description of the file provides the advantage of allowing a user to open only a selected file or files without burdening the computers resources.

In some applications, it may be desirable to perform one or more operations on the compressed file. Typical operations may include, but are not limited to, modifying a compressed file, emailing the compressed file, deleting the compressed file, verifying that the decompressed file matches the original source file, restoring the decompressed file to its original source location, and the like. These operations may be performed using the graphical user interface. As described above, a single set of data may be decompressed without decompressing each of the plurality of sets of data. Accordingly, a single file may be decompressed without decompressing other files. Thus, in one embodiment a compressed file may be modified by decompressing the file to a temporary folder and launching it using an appropriate software application. In this embodiment, the decompressed file in the temporary folder may be modified and then saved. Once the software application is terminated, the modified file may be moved back into the appropriate compression file folder and recompressed.

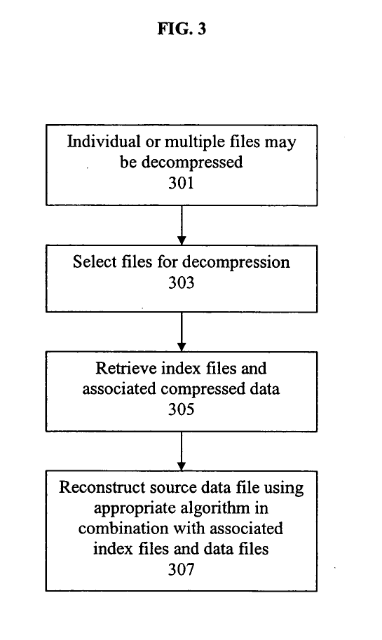

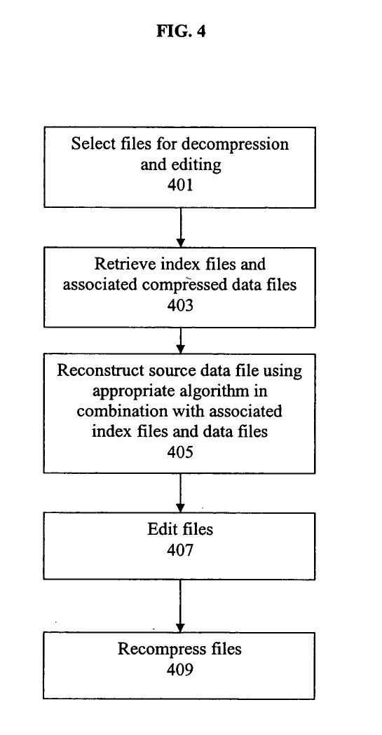

FIG. 3 is a flow chart showing exemplary steps in the decompression process. In one embodiment, individual or multiple files may be decompressed (Step 301). Preferably, one or more files are then selected for decompression (Step 303). As illustrated by step 305, the processor may decompress the files by, for example, retrieving the index files and associated compressed data files. The original, uncompressed source data file may then be reconstructed using, for example, one or more appropriate algorithms in combination with associated index files and data files (Step 307). As illustrated by FIG. 4, the files may also be decompressed and edited. In one embodiment, the files may be selected for decompression and editing (Step 401). The index files and associated compressed data files may then be retrieved (Step 403). The appropriate algorithms, in combination with associated index files and data files may then be used to reconstruct the original source files (Step 405). The files may then be edited (Step 407), and then recompressed (Step 409), as described above.

In another embodiment, the user interface may be used to add additional compressed files to the files that have already been compressed. In this embodiment, a decompressed file may be moved from a directory within the computer memory to one of the compression file folders. Upon being moved into one of the compression file folders, the file may be compressed and stored in the computer memory. Other functions may be performed using the user interface. For example, a selected compressed file may be emailed to another user. In this embodiment, the compressed file may be emailed by using an email option included in the user interface. Preferably, the file is transmitted in its compressed form. This provides the advantage of reducing the time and resources necessary to transmit the file to the email recipient. In another embodiment, the user interface may include a function that allows verification that a decompressed file matches the original source file. In other embodiments, the user interface may include a function that allows a decompressed file to be restored to its original source location. While the present invention has been described with respect to select computer operations, it will be understood by those skilled in the art that the present invention may be used in conjunction with any of a plurality of computer functions known to those skilled in the art, such as email, deletion, modification, restoration, display, transmission, and the like.

In some embodiments, the present invention may be capable of automatically managing files. For example, in one embodiment it may be preferable to automatically compress files that are stored on a computer memory. This may be accomplished using, for example, the user interface. In this embodiment, a user may pre-select files to be compressed according to factors including, but not limited to, a specific time, file size, file age, file type, and the like. In this embodiment, files that meet the desired criteria would be automatically placed into selected compression file folders and compressed automatically, without further user intervention. In other embodiments, the user interface may be used to prompt a user to change the importance level of a compressed file based on a desired factor, such as the frequency with which a file is accessed. Because computer memory space is limited, providing a prompt to change the importance level of a compressed file may provide the advantage of allowing faster archival of compressed files to another type of memory, such as a disk, CD-ROM, optical disk, or the like.

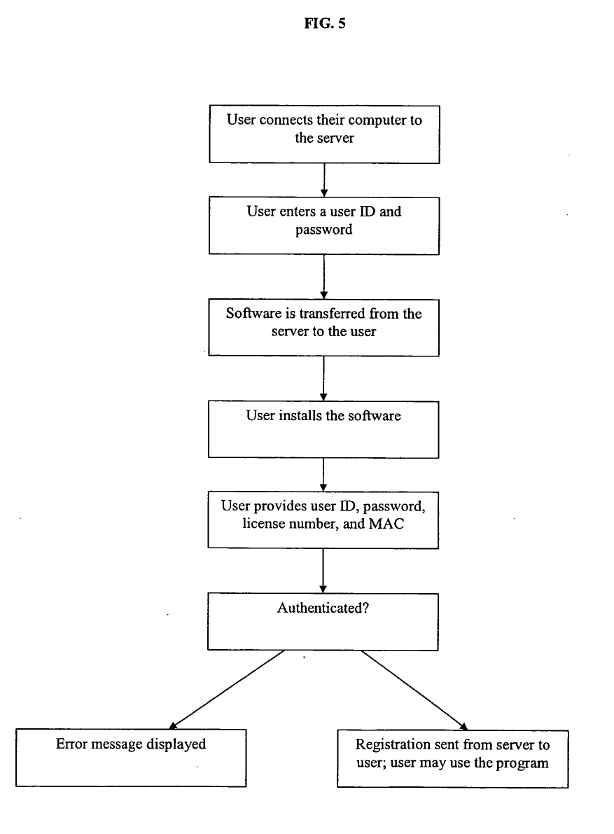

In one embodiment, the present invention may comprise a computer program product or software program. In such an embodiment, the software program may be transmitted to a user or network administrator over a WAN, such as the Internet. In this embodiment, shown in FIG. 5, a user connects their computer to a remote server by accessing a website on the Internet. The user preferably enters a user identification (ID) and password. The user ID and password may be acquired through the website, email, telephone, or any other convenient method. The appropriate software may then be transmitted from the remote server to the user's computer.

The user may then install the software onto their computer using, for example, an installation wizard. In order to prevent unauthorized users from using the software, the user preferably provides their user ID, password, license number, and Machine Address Code (MAC). The user's computer then communicates with the remote server via, for example, the Internet. If the user's information is authenticated, the user is able to request a registration key from the remote server. This information may be sent via any desired method, such as email, postal mail, telephone, and the like. After the registration key is provided to the software application, the software may be used to perform a variety of functions including, but not limited to, compressing files, decompressing files, managing files, outputting files, or accessing help files. If the user's information is not authenticated, an error massage may be displayed to the user indicating the information that was invalid and prompts the user to correct the invalid information.

Digital Identification Mark

In a preferred embodiment, the user interface may be used in applications involving electronic authentication. In this embodiment, the user interface may be capable of transferring a digital identification mark comprising a compressed data file over a data transmission medium. The data transmission medium may be a network such as a WAN, Local Area Network (LAN), or the like. In an embodiment involving authentication, files are compressed based on a compression ratio, as described in detail above. A digital identification mark including a unique authentication code may also be generated. Preferably, the digital identification mark is also compressed based on the algorithm that produces the best compression ratio, as described above. The compressed digital identification mark and the compressed files may then be combined and compressed according to the method described above. The combined files and digital identification mark may then be transmitted in a compressed form over a data transmission medium.

In one embodiment, the digital identification mark comprises a unique digital mark that may be attached to all communications, such as email, VoIP, and Instant Messaging. The digital identification mark may comprise a unique graphic image, picture; any desired textual information, and the like. In one embodiment, the digital identification mark may be used to authenticate any electronic transaction. For example, it may be desirable to authenticate a document or file that is to be transmitted. In this embodiment, a user selects one or more files to be electronically authenticated using the user interface. The authentication function may be part of the compression software described above, or it may be transmitted to a user from a server in a substantially similar manner. The file may be selected using any desired method, such as moving the file into an authentication folder, or selecting a file and then using a mouse cursor to select an authentication function included in the user interface. After selecting one or more files to be electronically authenticated, a user's digital identification mark may be sent to a remote server. The server may be the same as the server described above with respect to the compression software, or it may be a separate element. If the digital identification mark server is a separate element, it may be desirable for the compression software server and the digital identification server to be capable of communicating with each other.

Upon receiving the digital identification mark, specific information related to that request, such as time, owner profile, recipient, and the like, are recorded by the server. The server then modifies the users digital identification mark by adding unique information related to the particular transaction, such as the time of the transaction, owner profile, recipient, and the like. The information that is added preferably makes the digital identification mark unique for a given transaction. One advantage of changing the digital identification mark for every transaction is that the digital identification mark may only be used for a single transaction. In other words, the digital identification mark used for one transaction may not be used to authenticate another transaction. In one embodiment, each time a user uses the digital identification mark a copy of the event may be recorded and stored in a database that is operatively connected to the server. In some embodiments, it may be desirable to transmit an authenticated file to several users sequentially. In such an embodiment, each time a new digital identification mark is generated and stored in the database, it may be linked to previous digital identification marks. One advantage of this method is that the digital identification marks may be used to determine a “chain of custody” of identification mark ownership. In other words, the authenticity of the file may be verified as it is passed between users. In another embodiment, the authenticity may be verified by attaching each new digital identification mark to the digital identification mark that was previously attached. A user would then be able to see the digital signatures of each user who verified the document.

In other embodiments, the digital identification mark may be used to prevent identity theft. For example, if a document, such as a credit application is authenticated with a false digital identification mark, the digital identification mark may be submitted to the database for verification. The database and server may be capable of determining whether or not it was associated with the correct user. This may be a valuable tool for merchants, financial institutions and consumers, reducing risk and improving e-commerce business practices. The digital identification mark may also be used in transactions where an electronic identity needs to be verified, such as electronic signing of credit card transaction, signing legal documents, signing email, and the like. In the case of a credit card transaction, a copy of the signature may be recorded. In one embodiment, a user may access the database to verify whether or not a transaction and signature is valid.

In another embodiment, the digital identification mark may be used to authorize online purchases. While a user is at an ecommerce website, such as Amazon.com, they may request their digital identification mark from the server. In one embodiment, the digital identification mark application may be launched from, for example, the Menu Bar of the Internet Explorer. The Menu Bar may display an icon that allows a user to authorize a particular transaction. By selecting the icon, a unique digital identification mark may be generated by the server and attached to the current URL webpage address and transaction contents. This provides the advantage of allowing the online merchant to verify that the user has verified the transaction by attaching their digital identification mark. Preferably, a copy of this transaction may also be stored in the database to prevent a user from reneging on the transaction.

Although the present invention has been described with reference to particular embodiments, it will be understood to those skilled in the art that the invention is capable of a variety of alternative embodiments within the spirit of the appended claims.

1. A data compression method, comprising:
analyzing data based on a plurality of algorithms to determine a compression ratio for each algorithm; and
compressing the data based on the algorithm that produces the best compression ratio.

2. The data compression method according to claim 1, wherein the compressed data includes at least one index file that references the algorithm that produces the best compression ratio.

3. The data compression method according to claim 2, further comprising decompressing the compressed data based on a last index file that is attached to the data.

4. The data compression method according to claim 1, wherein said algorithms remove and index repeating bit patterns.

5. The data compression method according to claim 2, wherein the compression generates an encrypted data stream output.

6. The data compression method according to claim 1, wherein the compression is initiated manually or automatically based on a command from a user interface.

7. The data compression method according to claim 6, wherein a portion of the compressed data is decompressed based on said command.

8. The data compression method according to claim 6, further comprising introducing additional data, wherein the additional data is compressed and associated with the compressed data automatically.

9. The data compression method according to claim 6, further comprising compressing and associating a descriptive tag to said data based on the user interface.

10. A method of compressing data for transmission, comprising:
analyzing data based on a plurality of algorithms to determine a compression ratio for each algorithm;
compressing the data a first time based on the algorithm that produces the best compression ratio;
analyzing the compressed data based on the plurality of algorithms to determine a compression ratio for each algorithm; and
compressing the data iteratively based on the algorithm that produces the best compression ratio.

11. The method according to claim 10, wherein said algorithms remove repeating bit patterns.

12. The method according to claim 10, wherein said compressing the data the first time comprises attaching a first index file to the data.

13. The method according to claim 12, wherein said compressing the data iteratively comprises attaching an index file to the data for each iteration.

14. The method according to claim 13, wherein the index file references the algorithm that produces data with the least number of bits.

15. The method according to claim 14, wherein the compressed data is decompressed based on a last index file that is attached to the data.

16. The data compression method according to claim 10, wherein a portion of the compressed data is decompressed based on a command from a user interface.

17. The data compression method according to claim 10, further comprising selecting additional data, wherein the additional data is compressed and associated with the compressed data automatically.

18. The data compression method according to claim 16, further comprising compressing and associating a descriptive tag to said data based on a command from the user interface.

19. A method for transferring a digital identification mark with compressed data over a data transmission medium, comprising:
compressing data based on a plurality of algorithms to determine a data compression ratio associated with each algorithm;
iterative compression of the data based upon using the algorithm that produces the best data compression ratio;
generating a compressed digital identification mark having a unique authentication code;
data compression of said digital identification mark with a second set of compressed data to produce a single mass of compressed data; and
transmitting said single mass of compressed data over a data transmission medium.

20. The method according to claim 19, wherein said algorithms remove repeating bit patterns.

21. The method according to claim 19, wherein the compression is initiated manually or automatically based on a command from a user interface.

22. The method according to claim 19, wherein the digital identification mark comprises a graphic image.

23. The method according to claim 19, wherein the digital identification mark comprises text.

24. The method according to claim 19, wherein the digital identification mark comprises audio data.

25. The method according to claim 19, wherein the unique authentication code comprises at least one of time, owner profile, and identity of a recipient.
